(19) United States
(12) Patent Application Publication
(10) Pub. No.: US 2019/0252106 A1
(43) Pub. Date: Aug. 15, 2019

(54) LOW PASS FILTER

(71) Applicant: CKD Corporation, Aichi (JP)

(72) Inventors: Akihiro Ito, Aichi (JP); Masayuki Kouketsu, Aichi (JP); Masatoki Ito, Aichi (JP); Takashi Hosono, Aichi (JP)

(73) Assignee: CKD Corporation, Aichi (JP)

(21) Appl. No.: 16/393,374

(22) Filed: Apr. 24, 2019

Related U.S. Application Data
(63) Continuation of application No. PCT/JP2017/034127, filed on Sep. 21, 2017.

(30) Foreign Application Priority Data
Nov. 1, 2016 (JP) 2016-214639

(51) Int. Cl. H01F 27/08; H03H 7/01; H01F 27/40; H03H 3/00; H01F 41/06; H05K 7/20

(52) U.S. Cl. CPC H01F 27/08; H03H 7/0115; H01F 27/40; H05K 7/20145; H01F 41/06; H05K 7/20254; H03H 3/00

(57) ABSTRACT

A low pass filter including: a coil that includes a band-shaped conductor and is wound a plurality of times around an axis; a capacitor that has one terminal connected to the conductor and the other terminal connected to ground; a cooling plate in contact with an end surface of the wound coil with respect to a direction of the axis; and a ceramic layer that has a flat surface and is disposed on the end surface of the would coil facing the direction of the axis, wherein the ceramic layer contacts the cooling plate, and the cooling plate includes a flow path through which water flows.

### CROSS-REFERENCE TO RELATED APPLICATION

The present application is a continuation application of International Application No. PCT/JP2017/034127 filed on Sep. 21, 2017, and claims priority to Japanese Patent Application No. 2016-214639 filed on Nov. 1, 2016, both of which are incorporated by reference in their entirely.

### BACKGROUND

### Technical Field

The present invention relates to a low pass filter for eliminating high-frequency noise.

### Description of the Related Art

Conventionally, in order to eliminate high-frequency noise generated in an electric circuit, provision of a low pass filter in the circuit is widely practiced.

Equipment for which such a low pass filter is provided is, for example, a plasma generator described in Japanese Patent Application Laid-Open (kokai) No. 2010-10214. In the plasma generator described in this document, since an electric heater provided therein receives high-frequency noise, in order to suppress entry of high-frequency noise to a power source or the like from the electric heater, a low pass filter is provided between the electric heater and the power source so as to eliminate high-frequency noise.

A low pass filter needs to have a sufficiently large impedance at a frequency at which noise is to be eliminated; i.e., an object frequency. The greater the inductance of a coil, the more the frequency at which the impedance assumes a peak value shifts toward a low-frequency side. The smaller the inductance of the coil, the more the frequency at which the impedance assumes a peak value shifts toward a high-frequency side. That is, the lower the object frequency, the more the inductance of the coil needs to be increased. In order to increase the inductance of the coil, the number of windings of the coil needs to be increased, or the cross-sectional area of the coil needs to be increased for reducing copper loss, which increases the size of the entire low pass filter. Also, the larger the coil, the more the heat generated in the coil needs to be removed.

### SUMMARY

One or more embodiments of the present invention provide a low pass filter having small copper loss and allowing reduction in size.

A low pass filter according to one or more embodiments comprises a coil formed of a band-shaped conductor wound a plurality of times around a predetermined axis, a capacitor having one terminal connected to the conductor and the other terminal connected to a grounding part, and a cooling member in contact with an end surface side of the coil with respect to a direction of the predetermined axis.

Since one or more embodiments of the above configuration use the band-shaped conductor wound around the predetermined axis as the coil, an insulation member or the like is not provided between conductors with respect to the direction of the predetermined axis. Further, heat generated in the conductor of the coil is transmitted to an end portion of the coil with respect to the direction of the predetermined axis and can be efficiently removed by means of the cooling member provided on the end surface side with respect to the direction of the axis of the coil. Additionally, since only insulation in the radial direction of the coil suffices for insulation between layers of the conductor, an occupancy ratio indicative of the ratio of the volume of the conductor to the volume of the entire coil becomes large. Therefore, the resistance value of the coil per unit volume reduces, and thus the coil allows passage of specified current therethrough with a smaller volume; accordingly, the volume of the entire coil can be further reduced.

As a result, a low pass filter according to one or more embodiments exhibits superior heat removal and allows reduction in size.

According to one or more embodiments, the coil is formed such that a laminate including the conductor, an insulation member, and an adhesive member laminated in this order is wound a plurality of times around the predetermined axis.

In a general coil whose structure for insulating conductors from one another is previously determined, the inductance and impedance characteristics of the coil can be changed only by changing the diameter of the conductors and the number of windings. In this regard, according to one or more embodiments of the above configuration, since the impedance characteristic of the coil can be changed by changing the thickness of the insulation member, a coil having an appropriate impedance can be provided in accordance with the object frequency. Eventually, the impedance of the coil at the object frequency can be increased.

According to one or more embodiments, a frequency characteristic of the coil indicative of the relation between impedance of the coil and frequency is adjusted by means of the number of windings of the coil, the width of the conductor, and the thickness of the insulation member.

In one or more embodiments of the above configuration, since the frequency characteristic of the impedance of the coil is set by adjusting a plurality of factors which determines the size of the coil, a coil having an appropriate size can be provided for the object frequency. Particularly, even though the coil is restricted in the number of windings, the width of the conductor, etc., since the frequency characteristic of the impedance of the coil can be set through adjustment of the thickness of the insulation member, a coil having an appropriate impedance can be provided in accordance with the object frequency.

According to one or more embodiments, a frequency to be eliminated is predetermined as an object frequency, and a frequency at which the coil has a maximal impedance is shifted a predetermined frequency from the object frequency.

Since the frequency characteristic of the impedance of a coil involves an individual difference, even though the coil is designed such that the frequency at which the impedance of the coil becomes maximal coincides with the object frequency, in actuality, the impedance of the coil may fail to assume a maximal value at the object frequency in some cases. In this regard, according to one or more embodiments of the above configuration, since the frequency at which the impedance of the coil becomes maximal is shifted from the object frequency, even though the frequency characteristic of the impedance of the coil involves an individual difference, the tendency of the frequency characteristic is unlikely to change. Therefore, even though the frequency characteristic of the impedance of the coil involves an individual difference, the noise elimination performance of the entire low pass filter can be secured.

According to one or more embodiments, the frequency at which the coil has a maximal impedance is the predetermined frequency higher than the object frequency.

In order for the frequency at which the impedance of the coil becomes maximal to be lower than the object frequency, the inside diameter of the coil needs to be increased, or the number of windings of the coil needs to be increased; accordingly, the size of the coil further increases. In this regard, according to one or more embodiments of the above configuration, since the frequency at which the impedance of the coil becomes maximal is rendered higher than the object frequency, an increase in the size of the coil can be restrained.

According to one or more embodiments, the frequency at which the coil has a maximal impedance is the predetermined frequency lower than the object frequency.

In order for the frequency at which the impedance of the coil becomes maximal to be higher than the object frequency, the thickness of the insulation member of the coil needs to be further increased; accordingly, the size of the coil further increases. In this regard, according to one or more embodiments of the above configuration, since the frequency at which the impedance of the coil becomes maximal is rendered lower than the object frequency, an increase in the size of the coil can be restrained.

According to one or more embodiments, the object frequency is a frequency of 100 kHz to 20 MHz.

According to one or more embodiments of the above configuration, since the object frequency is a frequency at which higher inductance is required for elimination of noise, a low pass filter having superior cooling efficiency and allowing reduction in size can be more favorably used.

According to one or more embodiments, a plurality of the capacitors is provided, and the capacitors are connected in parallel.

According to one or more embodiments of the above configuration, while the minimal value of the impedance of each individual capacitor and the frequency at which the impedance assumes a minimal value are maintained, the overall impedance of the capacitors can be further reduced. Therefore, a low pass filter exhibits improved noise elimination performance.

According to one or more embodiments, the coil has a ceramic layer having a flat surface and provided on an end surface thereof facing in the direction of the predetermined axis, and the flat surface of the ceramic layer is in contact with the cooling member.

In the case of the coil formed by winding the conductor a plurality of times around the predetermined axis, at an end surface of the coil facing in the direction of the predetermined axis, recesses are formed between layers of the conductor, and some layers of the conductor protrude. As a result, when the cooling plate is brought into contact with the end surface of the coil facing in the axial direction, the transmission of heat from the coil to the cooling plate deteriorates. In this regard, according to one or more embodiments of the above configuration, since the coil has the ceramic layer having the flat surface and provided on the end surface of the coil facing in the direction of the predetermined axis, adhesion between the flat surface of the ceramic layer and the cooling member is enhanced. Therefore, the efficiency of heat radiation by the cooling member can be improved.

According to one or more embodiments, the cooling member has a flow path provided therein.

In one or more embodiments of the above configuration, since coolant such as water or air can be passed through the flow path formed in the cooling member, the effect of cooling can be further improved.

According to one or more embodiments, a plurality of the coils is in contact with a single piece of the cooling member.

In the case of provision of a plurality of pieces of equipment susceptible to reception of high-frequency noise, since the coils provided for pieces of equipment located in the vicinity of one another can be brought into contact with a single cooling member, the size of the shape of the entire low pass filter can be reduced. In the case of connection of equipment susceptible to reception of high-frequency noise to a power source, a control circuit, or the like, a combination of a coil and a capacitor needs to be provided in each of circuits on the positive side and the negative side of the equipment. In this regard, according to one or more embodiments of the above configuration, the coil provided on the positive side of the equipment and the coil provided on the negative side of the equipment can be brought into contact with a common cooling member, so that the size of the shape of the entire low pass filter can be reduced.

According to one or more embodiments, the cooling member has a plate shape, and at least one of the coils is in contact with each of front and back sides of the cooling member.

According to one or more embodiments of the above configuration, since the coil(s) is in contact with each of the opposite sides of the cooling member, the size of the entire low pass filter can be further reduced. In the case of connection of equipment susceptible to reception of high-frequency noise to a power source, a control circuit, or the like, a combination of a coil and a capacitor needs to be provided in each of circuits on the positive side and the negative side of the equipment. In this regard, according to the above configuration, the coil(s) on one side can be brought into contact with a first side of the cooling member, whereas the coil(s) on the other side can be brought into contact with a second side of the cooling member.

According to one or more embodiments, the coil is formed into a tubular shape by winding the band-shaped conductor a plurality of times in layers.

### BRIEF DESCRIPTION OF THE DRAWINGS

The features and advantages of one or more embodiments of the present invention will be apparent from the following detailed description with reference to the accompanying drawings.

FIG. 1 is a view showing the external appearance of a low pass filter according to one or more embodiments;

FIG. 2 is a sectional view taken along line A-A of FIG. 1;

FIG. 3 is an enlarged view of region B of FIG. 2;

FIG. 4 is a view showing the state of electrical connection between a coil and a capacitor according to one or more embodiments;

FIG. 5 is a circuit diagram of the low pass filter according to one or more embodiments;

FIG. 6 is a graph showing the frequency characteristics of the impedances of the coil and the capacitor according to one or more embodiments;

FIG. 7 is a graph showing changes in the frequency characteristic of the impedance of the coil when the number of windings of the coil is changed according to one or more embodiments;

FIG. 8 is a graph showing changes in the gain of the low pass filter when the number of windings of the coil is changed according to one or more embodiments;

FIG. 9 is a graph showing changes in the frequency characteristic of the impedance of the coil when the inside diameter of the coil is changed according to one or more embodiments;

FIG. 10 is a graph showing changes in the frequency characteristic of the impedance of the coil when the interlayer distance of the coil is changed according to one or more embodiments; and

FIG. 11 is a graph showing the frequency characteristic of impedance in the case where a plurality of capacitors is provided according to one or more embodiments.

### DETAILED DESCRIPTION OF EMBODIMENTS

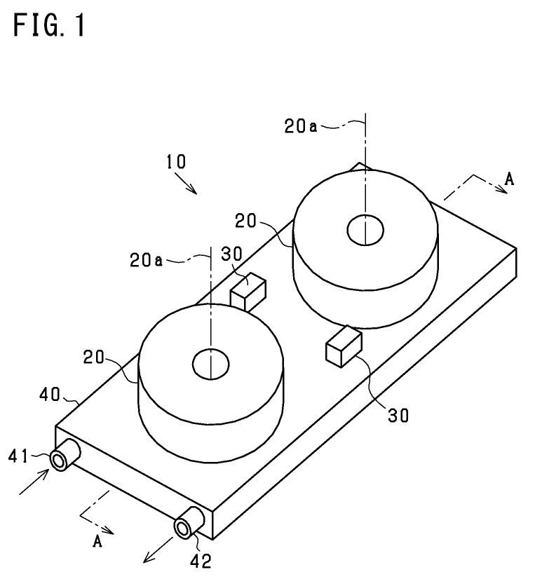

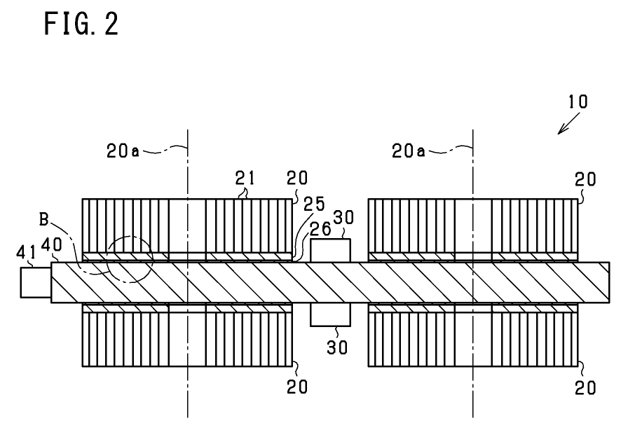

First, the structure of a low pass filter 10 will be described with reference to FIGS. 1 and 2. The low pass filter 10 includes coils 20 each formed such that a laminate 21 including a band-shaped conductor is wound a plurality of times in layers around a predetermined axis 20a, and capacitors 30 connected to the respective coils 20. Each coil 20 is formed such that adjacent portions of the laminate 21 are in close contact with each other in layers, and is formed into cylindrical shape having a hole at the center thereof. The shape of each coil 20 is not limited to a cylindrical shape, but may be a square tubular shape, etc.

The coils 20 and the capacitors 30 are attached to a plate-shaped cooling member (cooling plate) 40. Specifically, two coils 20 are provided on each of the front and back sides of the cooling member 40 in such a manner as to be spaced from each other in the longitudinal direction of the cooling member 40, and the end surfaces of the coils 20 facing in the direction of the predetermined axis 20a are in contact with the cooling member 40. Also, two capacitors 30 are provided between the coils 20 on each of the front and back sides of the cooling member 40 in such a manner as to be spaced from each other in the lateral direction of the cooling member.

The cooling member 40 is formed of, for example, aluminum oxide (alumina) and has a flow path formed therein for allowing flow of a liquid or gas coolant. The cooling member 40 has a flow path inlet 41, which is an inlet for the coolant, and a flow path outlet 42, which is an outlet for the coolant, provided at a longitudinal side face thereof. Notably, in one or more embodiments, water is used as the coolant.

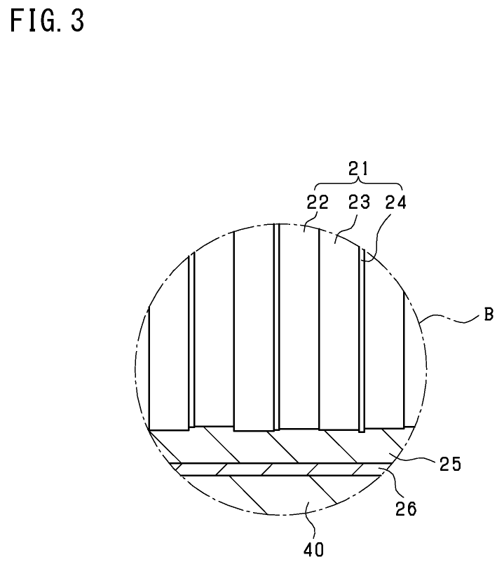

As shown in the enlarged sectional view of FIG. 3, a laminate 21 includes a band-shaped (narrow-film-shaped) conductor 22, a band-shaped insulation member (film) 23, and a band-shaped adhesive member (film) 24, and the conductor 22, the insulation member 23, and the adhesive member 24 are laminated in this order. The conductor 22 is formed of copper. The insulation member 23 is formed of, for example, polyimide. The adhesive member 24 is formed of, for example, silicone adhesive.

In forming each coil 20 in such a manner mentioned above, at an end surface of the coil 20 facing in the direction of the predetermined axis 20a, some layers of the conductor 22 and the insulation member 23 protrude, resulting in formation of recesses between layers of the conductor 22. Thus, as shown in the enlarged sectional view of FIG. 3, a ceramic layer 25 is formed by thermal spraying of alumina on the axial end surface of the coil 20 in such a manner as to fill recesses between layers of the conductor 22. As a result, the axial end surface of the coil 20 is covered with the ceramic layer 25. Since alumina is an insulating material, even though alumina is thermally sprayed onto the conductor 22, a short circuit between layers of the conductor 22 can be prevented. The surface of the ceramic layer 25 facing in the direction of the predetermined axis is flattened by grinding to predetermined smoothness.

The cooling member 40 and the surface of the ceramic layer 25 facing in the direction of the predetermined axis are bonded together by an adhesive member 26 having thermal conductivity. The adhesive member 26 is, for example, silicone adhesive and has a linear expansion coefficient roughly equal to that of the cooling member 40.

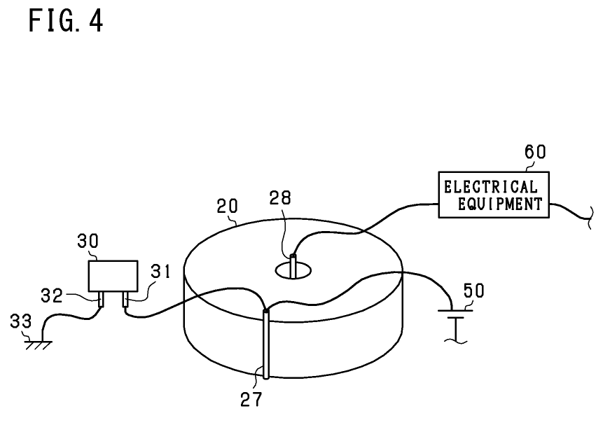

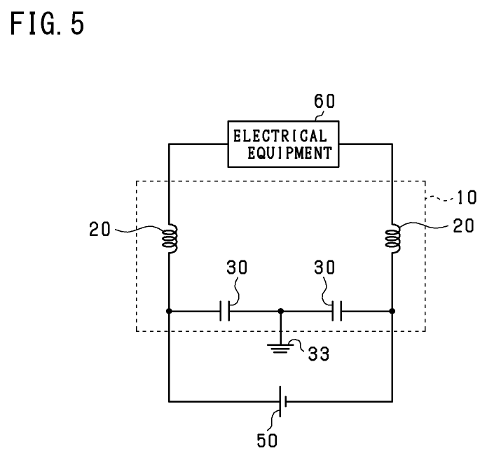

Next, an electrical connection between the coils 20 and the capacitors 30 in the low pass filter 10 will be described with reference to FIGS. 4 and 5. Notably, in FIG. 4, an illustration of the low pass filter 10 provided on the negative side of an electrical equipment 60 and a DC power source 50 is omitted. The conductor 22 of each coil 20 has a first terminal 27 and a second terminal 28 provided respectively at opposite longitudinal end portions thereof. As mentioned above, since the coil 20 is formed by winding the conductor 22 around the predetermined axis 20a, the first terminal 27 is provided at the outermost circumference of the coil 20, and the second terminal 28 is provided at the innermost circumference of the coil 20. The capacitor 30 has a first terminal 31 and a second terminal 32.

The first terminal 31 of the capacitor 30 and the DC power source 50 are connected to the first terminal 27 of the coil 20. The electrical equipment 60 is connected to the second terminal 28 of the coil 20. The second terminal 32 of the capacitor 30 is connected to a grounding part 33, i.e., connected to ground. By virtue of such connection between the low pass filter 10, the DC power source 50, and the electrical equipment 60, electrical noise generated in the electrical equipment 60 or electrical noise received by the electrical equipment 60 can be eliminated by the low pass filter 10.

As shown in FIG. 5, in the low pass filter 10, a pair consisting of the coil 20 and the capacitor 30 is provided on each of the positive side and the negative side of the DC power source 50. Therefore, in the configuration of the low pass filter 10 shown in FIGS. 1 to 3, the coil 20 and the capacitor 30 provided on the positive side of the DC power source 50 may be provided on one side of the cooling member 40, whereas the coil 20 and the capacitor 30 provided on the negative side of the DC power source 50 may be provided on the other side of the cooling member 40. Also, the coils 20 and the capacitors 30 provided on the positive side and the negative side of the DC power source 50 may be provided on one side of the cooling member 40.

In the thus-configured low pass filter 10, in order to increase the gain for noise having an object frequency, at which noise is to be eliminated, the impedance characteristic of the coil 20 and the impedance characteristic of the capacitor 30 need to be set.

With Vin representing a voltage to be input to the low pass filter 10, Vout representing the voltage output from the low pass filter 10, ZL representing the impedance of the coil 20, and ZC representing the impedance of the capacitor 30, the following expression (1) holds true.

$$\begin{matrix}[ Expression 1 ] & \\ Vout = \frac{ZC}{ZL + ZC} \cdot Vin & ( 1 )\end{matrix}$$

Specifically, the greater the value of ZL representing the impedance of the coil 20, the smaller the value of Vout representing the output voltage, and the lower the impedance of the capacitor 30, the smaller the value of Vout representing the output voltage.

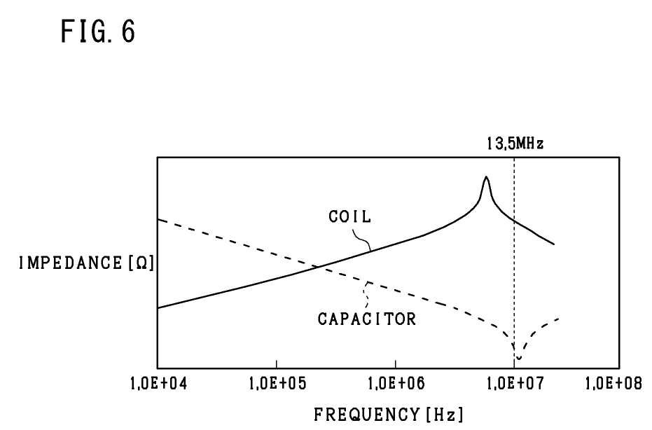

The frequency characteristic (indicative of the relation between impedance and frequency) of the coil 20, and the frequency characteristic of the capacitor 30 will be described with reference to FIG. 6. The frequency characteristic of the impedance of the capacitor 30 is as follows: the higher the frequency, the lower the impedance, and after the impedance assumes a minimal value at a certain frequency, the higher the frequency, the higher the impedance.

By contrast, the frequency characteristic of the impedance of the coil 20 is as follows: the higher the frequency, the higher the impedance, and after the impedance assumes a maximal value at a certain frequency, the higher the frequency, the lower the impedance.

As mentioned above, in order to sufficiently attenuate noise having an object frequency, the impedance of the coil 20 needs to be increased to a greater extent, and impedance of the capacitor 30 needs to be reduced to a greater extent. That is, the object frequency can be favorably eliminated by means of impedance of the coil 20 assuming a maximal value in the vicinity of the object frequency, and impedance of the capacitor 30 assuming a minimal value in the vicinity of the object frequency. For example, as shown in FIG. 6, with an object frequency of 13.6 MHz, noise having the object frequency can be favorably eliminated by setting the frequency at which the impedance of the capacitor 30 assumes a minimal value to be higher than the object frequency, and setting the frequency at which the impedance of the coil 20 assumes a maximal value to be lower than the object frequency.

Meanwhile, in one or more embodiments, the capacitor 30 has a predetermined impedance frequency characteristic. Thus, in the low pass filter 10 according to one or more embodiments, each coil 20 is designed such that the frequency at which the impedance of the coil 20 assumes a maximal value approximates the object frequency. Specifically, as shown in FIG. 6, the coil 20 is designed such that if the frequency at which the impedance of the capacitor 30 assumes a minimal value is a first predetermined value greater than the object frequency, the frequency at which the impedance of the coil 20 assumes a maximal value is a second predetermined value smaller than the object frequency.

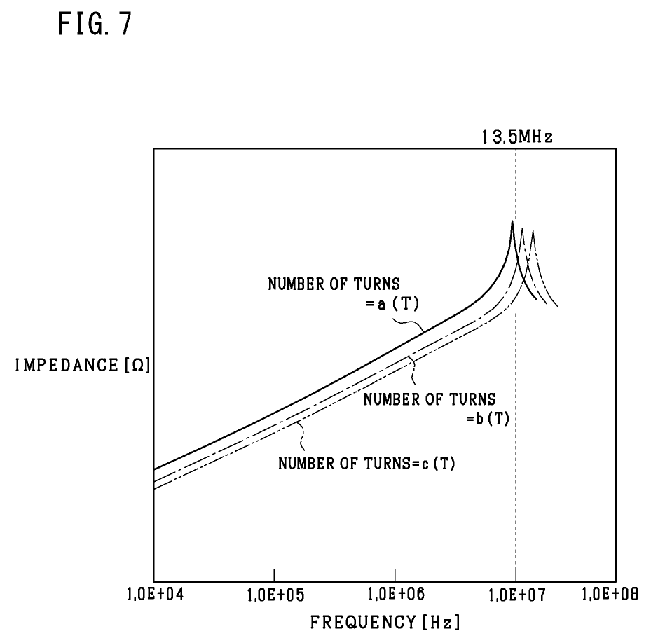

FIG. 7 shows the relation between the frequency characteristic of the impedance of the coil 20 and the number of windings of the coil 20. FIG. 7 shows the frequency characteristic of the impedance of the coil 20 for the case where the number of windings of the coil 20 is a(T), the case where the number of windings of the coil 20 is b(T), and the case where the number of windings of the coil 20 is c(T) (a>b>c). As shown in FIG. 7, as the number of windings increases, the frequency at which the impedance of the coil 20 assumes a maximal value shifts toward a low-frequency side, whereas as the number of windings reduces, the frequency at which the impedance of the coil 20 assumes a maximal value shifts toward a high-frequency side. That is, the lower the object frequency, the more the number of windings needs to be increased.

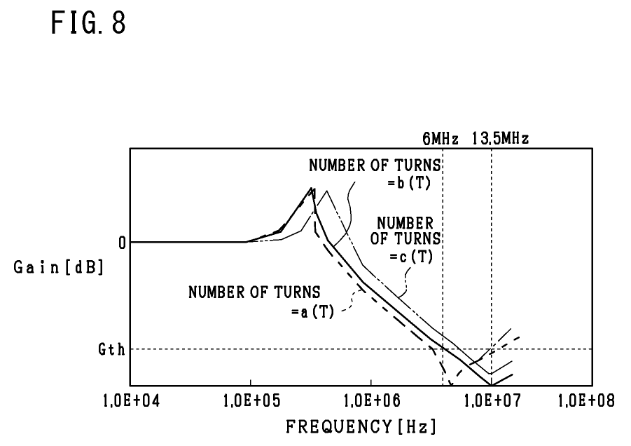

FIG. 8 shows changes in the gain of the low pass filter 10 when the number of windings of the coil 20 is changed on the condition that the electrostatic capacity of the capacitor 30 is fixed. In FIG. 8, a gain at which the low pass filter 10 can sufficiently eliminate noise is specified as a threshold value Gth.

As shown in FIG. 8, at an object frequency of 13.5 MHz, the gain becomes smaller than the threshold value Gth in the case where the number of windings is b(T) and the case where the number of windings is c(T), and the gain becomes greater than the threshold value Gth in the case where the number of windings is a(T). By contrast, at an object frequency of 6 MHz, the gain becomes smaller than the threshold value Gth in the case where the number of windings is a(T), and the gain becomes greater than the threshold value Gth in the case where the number of windings is b(T) and the case where the number of windings is c(T).

In order to render the gain at the object frequency smaller than the threshold value Gth, the inside diameter of the coil 20 may be changed instead of changing the number of windings of the coil 20 as mentioned above.

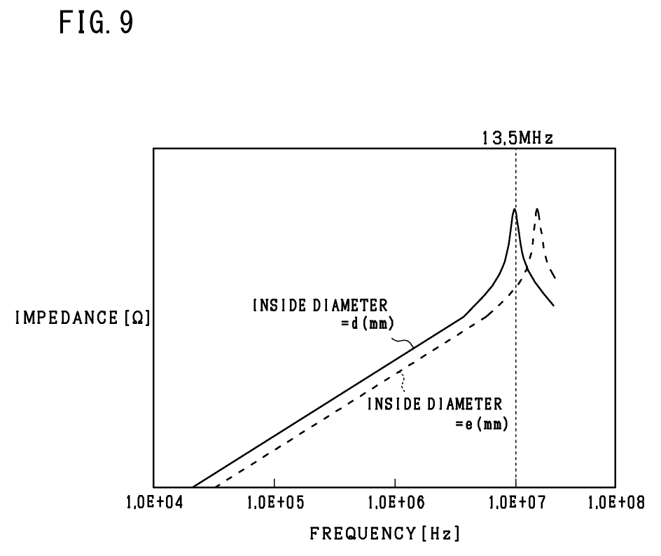

FIG. 9 shows the relation between the frequency characteristic of the impedance of the coil 20 and the inside diameter of the coil 20. FIG. 9 shows the frequency characteristic of the impedance of the coil 20 for the case where the inside diameter of the coil 20 is d(mm) and the case where the inside diameter of the coil 20 is e(mm) (d>e). As shown in FIG. 9, as the inside diameter increases, the frequency at which the impedance of the coil 20 assumes a maximal value shifts toward the low-frequency side, whereas as the inside diameter reduces, the frequency at which the impedance of the coil 20 assumes a maximal value shifts toward the high-frequency side. That is, the lower the object frequency, the more the inside diameter needs to be increased.

As mentioned above, the frequency characteristic of the impedance of the coil 20 is such that by means of changing the number of windings of the coil 20 and the inside diameter of the coil 20, the frequency at which the impedance of the coil 20 assumes a maximal value can approximate the object frequency.

However, the lower the elimination frequency, the more the number of windings of the coil 20 needs to be increased, and the more the inside diameter of the coil 20 needs to be increased. In this case, the length of the conductor 22 of the coil 20 increases; as a result, the resistance value of the coil 20 increases. That is, the coil 20 increases in copper loss. Thus, according to one or more embodiments, in addition to the number of windings and the inside diameter of the coil 20, the thickness of the insulation member 23 is changed, thereby changing the frequency characteristic of the impedance of the coil 20.

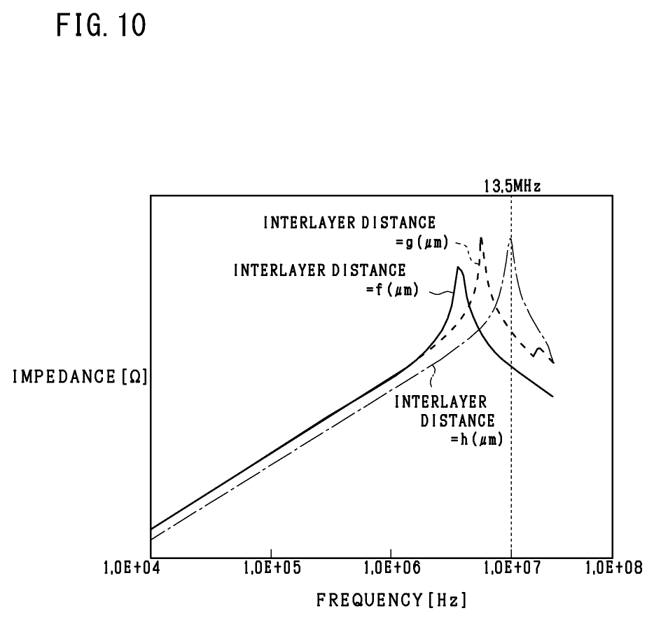

The relation between the frequency characteristic of the impedance of the coil 20 and the interlayer distance of the conductor 22 will be described with reference to FIG. 10. As mentioned above, since the insulation member 23 and the adhesive member 24 are provided between layers of the conductor 22, only the thickness of the insulation member 23 needs to be changed for changing the interlayer distance. FIG. 10 shows the frequency characteristic of the impedance of the coil 20 for the case where the interlayer distance is f (μm), the case where the interlayer distance is g (μm), and the case where the interlayer distance is h (μm) (f<g<h). As shown in FIG. 10, as the interlayer distance increases, the frequency at which the impedance of the coil 20 assumes a maximal value shifts toward the high-frequency side, whereas as the interlayer distance reduces, the frequency at which the impedance of the coil 20 assumes a maximal value shifts toward the low-frequency side. That is, by means of increasing the thickness of the insulation member 23, the frequency at which the impedance of the coil 20 assumes a maximal value can be shifted toward the high-frequency side, whereas by means of reducing the thickness of the insulation member 23, the frequency at which the impedance of the coil 20 assumes a maximal value can be shifted toward the low-frequency side.

By virtue of the above configuration, the low pass filter 10 according to one or more embodiments yields the following effects.

Since the band-shaped conductor 22 wound around the predetermined axis is used as each of the coils 20, there is not provided the insulation member 23 or the like between the conductors 22 with respect to the direction of the predetermined axis. Further, heat generated in the conductor 22 of each coil 20 is transmitted to an end portion of the coil 20 with respect to the direction of the predetermined axis and can be efficiently removed by means of the cooling member 40 provided on the end surface side of the coil 20 with respect to the direction of the predetermined axis. Additionally, since only insulation in the radial direction of the coil 20 suffices for insulation between layers of the conductor 22, an occupancy ratio indicative of the ratio of the volume of the conductor 22 to the volume of the entire coil 20 becomes large. Therefore, the resistance value of the coil 20 per unit volume reduces, and thus the coil 20 allows passage of specified current therethrough with a smaller volume; accordingly, the volume of the entire coil 20 can be further reduced. As a result, a low pass filter 10 exhibits superior heat removal and allows reduction in size.

In a general coil 20 whose structure for insulating the conductors 22 from one another is previously determined, the inductance and impedance characteristics of the coil 20 can be changed only by changing the diameter of the conductors 22 and/or the number of windings. In this regard, according to one or more embodiments, since the impedance characteristic of the coil 20 can be changed by changing the thickness of the insulation member 23, the coil 20 having an appropriate impedance can be provided in accordance with the object frequency. Eventually, the impedance of the coil 20 at the object frequency can be increased.

The lower the object frequency, the more the number of windings of the coil 20 needs to be increased, and/or the more the inside diameter of the coil 20 needs to be increased; as a result, copper loss increases. In this regard, according to one or more embodiments, the frequency at which the impedance of the coil assumes a maximal value approximates the object frequency by means of adjusting the thickness of the insulation member 23 provided between layers of the conductor in addition to adjustment of the number of windings of the coil 20 and the inside diameter of the coil 20. Thus, while copper loss of the coil 20 is restrained, the frequency at which the impedance of the coil assumes a maximal value can approximate the object frequency.

Since the frequency characteristic of the impedance of the coil 20 involves an individual difference, even though the coil 20 is designed such that the frequency at which the impedance of the coil 20 becomes maximal coincides with the object frequency, in actuality, the impedance of the coil 20 may fail to assume a maximal value at the object frequency in some cases. In this regard, according to one or more embodiments, since the frequency at which the impedance of the coil 20 becomes maximal is shifted from the object frequency, even though the frequency characteristic of the impedance of the coil 20 involves an individual difference, the tendency of the frequency characteristic is unlikely to change. Therefore, even though the frequency characteristic of the impedance of the coil 20 involves an individual difference, the noise elimination performance of the entire low pass filter 10 can be secured.

Since the frequency characteristic of the impedance of the coil 20 is set by adjusting a plurality of factors which determines the size of the coil 20, the coil 20 having an appropriate size can be provided for the object frequency. Particularly, even though the coil 20 is restricted in the number of windings, the inside diameter, etc., since the frequency characteristic of the impedance of the coil 20 can be set through adjustment of the thickness of the insulation member 23, the coil 20 having an appropriate impedance can be provided in accordance with the object frequency.

In the case of the coil 20 formed by winding the conductor 22 a plurality of times around the predetermined axis, at an end surface of the coil 20 facing in the direction of the predetermined axis, recesses are formed between layers of the conductor 22, and some layers of the conductor 22 protrude. As a result, when the cooling plate is brought into contact with the end surface of the coil 20 facing in the direction of the predetermined axis, the transmission of heat from the coil 20 to the cooling plate deteriorates. In this regard, according to one or more embodiments, since the coil 20 has the ceramic layer having the flat surface and provided on the end surface of the coil 20 facing in the direction of the predetermined axis, adhesion between the flat surface of the ceramic layer 25 and the cooling member 40 can be enhanced. Accordingly, the efficiency of heat radiation by the cooling member 40 can be improved.

Since the cooling member 40 has a structure in which water is passed through a flow path provided therein, the cooling effect can be further enhanced.

In the case of connection of the electrical equipment 60 susceptible to reception of high-frequency noise to the DC power source 50, a combination of a coil and the capacitor 30 needs to be provided in each of circuits on the positive side and the negative side of the equipment. In this regard, according to one or more embodiments, the coil 20 provided on the positive side of the equipment and the coil 20 provided on the negative side of the equipment are brought into contact with the common cooling member 40, so that the size of the shape of the entire low pass filter 10 can be reduced.

In one or more embodiments, one piece of the capacitor 30 is connected to one piece of the coil 20. In this regard, in one or more embodiments, a plurality of; specifically, two capacitors 30 are connected to a single piece of the coil 20.

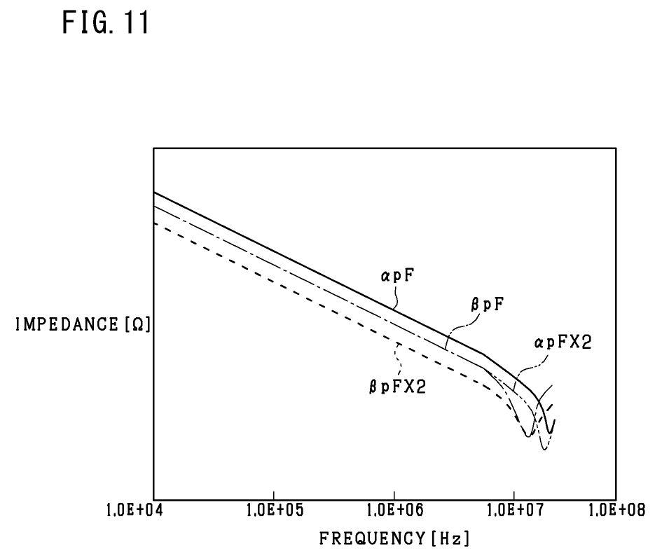

The frequency characteristic of the impedance of the capacitor 30 will be described with reference to FIG. 11. FIG. 11 shows the frequency characteristic of the impedance of the capacitor 30 for the case where a single capacitor 30 having an electrostatic capacity of α pF is used, the case where two capacitors 30 each having an electrostatic capacity of α pF are connected in parallel, the case where a single capacitor 30 having an electrostatic capacity of β pF is used, and the case where two capacitors 30 each having an electrostatic capacity of β pF are connected in parallel. Notably, the value of β is approximately twice the value of α.

As shown in FIG. 11, the frequency at which the impedance of a single capacitor 30 having an electrostatic capacity of α pF assumes a minimal value is approximately equal to the frequency at which the overall impedance of two capacitors 30 each having an electrostatic capacity of α pF and connected in parallel assumes a minimal value.

Meanwhile, the overall impedance of two capacitors 30 each having an electrostatic capacity of α pF and connected in parallel is approximately equal to the impedance of a single capacitor 30 having an electrostatic capacity of β pF. That is, the overall impedance of two capacitors 30 each having an electrostatic capacity of α pF and connected in parallel is lower than the impedance of a single capacitor 30 having an electrostatic capacity of α pF.

Therefore, by means of using a plurality of the capacitors 30 connected in parallel, while the frequency at which the impedance of each individual capacitor 30 assumes a minimal value is maintained, the overall impedance of the capacitors 30 can be further reduced, whereby the low pass filter 10 exhibits improved noise elimination performance.

<Modifications>

In the above embodiments, the frequency at which the impedance of the capacitor 30 assumes a minimal value is rendered higher than the object frequency; however, the frequency at which the impedance of the capacitor 30 assumes a minimal value may be rendered lower than the object frequency. In this case, the frequency at which the impedance of the coil 20 assumes a maximal value may be rendered higher than the object frequency. That is, the frequency at which the impedance of the coil 20 assumes a maximal value may be increased to a greater extent. As described in the above embodiments, for increasing the frequency at which the impedance of the coil 20 assumes a maximal value, the number of windings of the coil 20 may be reduced, and/or the inside diameter of the coil 20 may be reduced. Therefore, the coil 20 can be further reduced in size and can be reduced in copper loss.

The above embodiments exemplify an object frequency of 6 MHz and 13.5 MHz; however, the object frequency is not limited thereto. In one or more embodiments, a frequency of 100 kHz may be the lower limit of the elimination object frequencies of the low pass filters 10 according to the above embodiments. Also, in one or more embodiments, a frequency of 20 MHz may be the upper limit of the elimination object frequencies. This is for the following reason: as mentioned in the above embodiments, the higher the object frequency, the more the size of the coil 20 reduces; as a result, since generation of heat is reduced, the need to remove heat from the coil 20 by means of the cooling member 40 reduces.

In the above embodiments, the coils 20 are in contact with each of the front and back sides of the cooling member 40; however, the coils and the capacitors 30 may be provided on only one of the front and back sides.

In the above embodiments, a plurality of coils 20 is in contact with the cooling member 40; however, only one coil 20 may be in contact with the cooling member 40.

The above embodiments exemplify the case where a single object frequency is present; however, one or more embodiments are applicable to the case where a plurality of elimination object frequencies is present. For example, in the case where noise having a frequency of a few MHz and noise having a frequency of a few hundred kHz must be eliminated, the number of windings of the coil 20, the inside diameter of the coil 20, and the thickness of the insulation member 23 may be designed while using the frequencies of the noises as elimination object frequencies.

In the above embodiments, water is passed through the flow path provided in the cooling member 40; however, liquid other than water, or gas such as air may be passed as coolant.

In the above embodiments, the cooling member 40 has the flow path provided therein for passing water; however, the flow path may not be provided therein.

In the above embodiments, two capacitors 30 are connected in parallel; however, three or more capacitors 30 may be connected in parallel.

Materials for members of the low pass filter 10 are not limited to those mentioned in the above embodiments, but may be changed.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### DESCRIPTION OF REFERENCE NUMERALS

10: low pass filter; 20: coil; 20a: predetermined axis; 22: conductor; 23: insulation member; 25: ceramic layer; 30: capacitor; 33: grounding part; and 40: cooling member.

What is claimed is:

1. A low pass filter comprising:
a coil that comprises a band-shaped conductor and is wound a plurality of times around an axis;
a capacitor that has one terminal connected to the conductor and the other terminal connected to ground;
a cooling plate in contact with an end surface of the wound coil with respect to a direction of the axis; and
a ceramic layer that has a flat surface and is disposed on the end surface of the would coil facing the direction of the axis, wherein
the ceramic layer contacts the cooling plate, and
the cooling plate comprises a flow path through which water flows.

2. A low pass filter according to claim 1, wherein the coil comprises a laminate having the conductor, an insulation film, and an adhesive film laminated in this order, and the laminate is wound a plurality of times around the axis.

3. A low pass filter according to claim 2, wherein a frequency characteristic of the coil indicative of the relation between impedance of the coil and frequency is adjustable based on a number of windings of the coil, a width of the conductor, and a thickness of the insulation film.

4. A low pass filter according to claim 1, wherein a frequency to be eliminated is predetermined as an object frequency, and
a frequency at which the coil has a maximal impedance is shifted a predetermined frequency from the object frequency.

5. A low pass filter according to claim 4, wherein the frequency at which the coil has the maximal impedance is the predetermined frequency higher than the object frequency.

6. A low pass filter according to claim 4, wherein the frequency at which the coil has the maximal impedance is the predetermined frequency lower than the object frequency.

7. A low pass filter according to claim 4, wherein the object frequency is a frequency of 100 kHz to 20 MHz.

8. A low pass filter according to claim 1, wherein a plurality of the capacitors is connected in parallel.

9. A low pass filter according to claim 1, wherein a plurality of the coils is in contact with the cooling plate.

10. A low pass filter according to claim 9, wherein at least one of the coils contacts each of front and back sides of the cooling plate.

11. A low pass filter according to claim 1, wherein the wound layered coil has a tubular shape.

12. A method for producing a low pass filter that comprises: a coil that comprises a band-shaped conductor and is wound a plurality of times around an axis; a capacitor that has one terminal connected to the conductor and the other terminal connected to ground; and a cooling plate in contact with an end surface of the coil with respect to a direction of the axis, the method comprising the step of:
forming the coil by winding a laminate including the conductor, an insulation film, and an adhesive film laminated in this order; and
determining frequency characteristic of the coil indicative of the relation between impedance of the coil and frequency by adjusting a number of windings of the coil, a width of the conductor, and a thickness of the insulation film.

13. A method for producing a low pass filter according to claim 12, wherein a frequency of noise to be eliminated is predetermined as an object frequency, and
shifting a frequency at which the coil has a maximal impedance from the object frequency by a predetermined frequency.

14. A method for producing a low pass filter according to claim 13, wherein the frequency at which the coil has the maximal impedance is the predetermined frequency higher than the object frequency.

15. A method for producing a low pass filter according to claim 13, wherein the frequency at which the coil has the maximal impedance is the predetermined frequency lower than the object frequency.
